(19) United States
(12) Patent Application Publication
(10) Pub. No.: US 2003/0162403 A1
(43) Pub. Date: Aug. 28, 2003

(54) Method to eliminate antenna damage in semiconductor processing

(76) Inventor: Ju-Ai Ruan, Plano, TX (US)

Correspondence Address: TEXAS INSTRUMENTS INCORPORATED, P O BOX 655474, M/S 3999, DALLAS, TX, 75265

(21) Appl. No.: 10/085,758

(22) Filed: Feb. 28, 2002

(51) Int. Cl. H01L 21/302

(52) U.S. Cl. 438/710

(57) ABSTRACT

A method for reducing/eliminating plasma damage in semiconductor wafer (100) processing is introduced. The method is applicable to most semiconductor processes that involves the use of plasma, and does not affect process results other than reducing antenna damage. After exposing the wafer (100) to plasma excited gases (108), a cooling/idle step is added to allow the plasma to discharge prior to removing the wafer (100) from the process chamber (104).

### FIELD OF THE INVENTION

The invention is generally related to the field of semiconductor plasma processing and more specifically to eliminating antenna damage that can occur during semiconductor plasma processing.

### BACKGROUND OF THE INVENTION

Antenna damage is a quite common phenomena in semiconductor processes that involve a plasma. Examples of such processes include plasma enhanced chemical-vapor-deposition (PECVD), plasma etch, and high-density-plasma (HDP) processes. Antenna damages occurs when the charge collected in the antenna (e.g., a metal layer) stresses the oxide of a device. More specifically, in a MOSFET structure, the charge collected on the antenna stresses the gate oxide of the MOSFET, thereby inducing stress-related degradation of the MOSFET. This stress-related degradation may include: shortening the lifetime of the device, increasing the gate leakage of the device, or shifting the threshold voltage of the device.

Engineering solutions were often needed to reduce/eliminate antenna damage. Generally, the solutions involve changing critical process parameters that are used during the manufacturing process. For example, some solutions involved reducing certain plasma power or the transition of plasma power during different process steps. These solutions are useful, but the changes normally affect the process results. Sometimes the result is undesirable and additional adjustments are then required to ensure an acceptable end result. Therefore, a method for reducing or eliminating plasma damage without upsetting critical process parameters is desired.

### BRIEF DESCRIPTION OF THE DRAWINGS

In the drawings:

FIG. 1 is a cross-sectional diagram of a semiconductor body undergoing plasma treatment according to an embodiment of the invention;

FIG. 2 is a graph of diode leakage induced by antenna damage for various wafer splits;

FIG. 3 is a graph of diode leakage induced by antenna damage for various wafer splits including clamp and no clamp versions.

### DETAILED DESCRIPTION OF THE EMBODIMENTS

The inventors have discovered that, in many cases, antenna damage actually occurs after processing while the wafers are being moved out of the chamber. This is due to the fact that the process chamber is still full of residue charges from the plasma. Therefore, in the plasma process according to the invention, a wait step is added to allow the charges to dissipate before moving the wafers out of the chamber. The wafers may also be cooled down to increase resistance to antenna damage.

An embodiment of the invention will now be described in conjunction with a PSG (phosphorus doped silicate glass) deposition process at a pre-metal dielectric (PMD) level. It will be apparent to those of ordinary skill in the art that the benefits of the invention may be applied to semiconductor plasma processes in general. Examples include, but are not limited to, PECVD processes, plasma etch processes, and HDP processes.

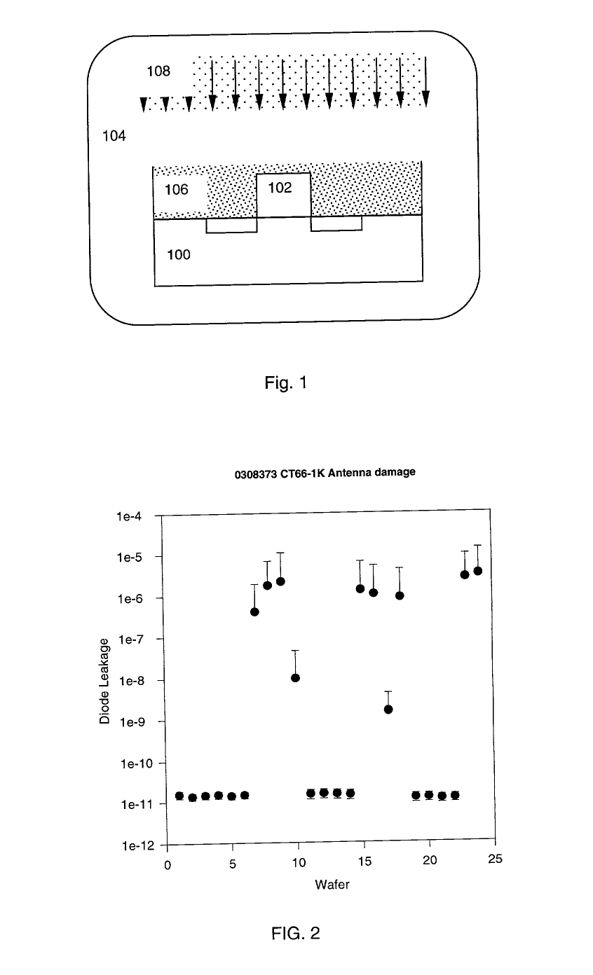

Referring to FIG. 1, a semiconductor wafer 100 is processed through the formation of transistor 102. The wafer 100 is then transferred to a process chamber 104, for example a HDP chamber. The PMD 106 is deposited within the process chamber using a standard recipe that uses plasma excited reactant gas mixture 108. For example, the following recipe may be used: high frequency RF power=3250W, low frequency RF power=3750W, PH₃=64 sccm, SiH₄=76 sccm, O₂=235 sccm.

After deposition, a cooling/idle step is added before moving the wafers. The duration of the cooling/idle is determined by the time it takes the plasma charges to discharge. For example, the duration may be in the range of 10-60 seconds. By allowing the plasma charges to be discharged, antenna damage is reduced or even eliminated.

After the cooling/idle step, the wafer 100 is removed from the chamber 104 and processing continues as normal. The cooling/idle step is independent of the main process parameters and therefore does not affect the other process results (e.g., deposition rate, film properties, etc.).

Test 1:Test wafers were split into four major groups to evaluate antenna damage. Group 1 consisted of a baseline PSG deposition using SACVD (sub-atmospheric chemical vapor deposition), a non-plasma process. Group 2 consisted of an HDP-PSG process in which wafers were removed from the process chamber immediately after PSG deposition. Group 3 consisted of an HDP-PSG process in which wafers were clamped after deposition for 30 seconds and then removed from the chamber. Clamping helped to cool the wafers to ˜300° C. Group 4 used a vendor best known process in which the wafers were removed from the chamber immediately after deposition. Within groups 2 and 3, additional splits were made to examine the effect of plasma power (high frequency-HF vs. low frequency-LF) and the effect of having a thin undoped oxide liner before PSG deposition. See Table I for wafer splits.

The results of test 1 are shown in FIG. 2. FIG. 2 shows that antenna damage level in groups 3 (wafer 11-14, 19-22, clamped) is compatible to group 1 (wafers 1-6, SACVD, non-plasma process). Group 2 (no clamp, wafers 7-10 15-18) and group 4 (vendor BKM, wafers 23-24) showed substantial diode leakage induced by antenna damage. This showed the effectiveness of clamping to reduce antenna damage.

TABLE I
Wafer split table used in test 1.

| Group | Sub-Group | Wafer | Description | Clamp |
|---|---|---|---|---|
| 1 | 1 | 1-6 | SACVD PSG | N/A |
| 2 | 2 | 7 | Low LF, Low HF, no liner | No |
| 2 | 3 | 8 | Low LF, high HF, no liner | No |
| 2 | 4 | 9 | Low LF, low HF, with liner | No |
| 2 | 5 | 10 | Low LF, High HF, with liner | No |
| 2 | 10 | 15 | High LF, Low HF, no liner | No |
| 2 | 11 | 16 | High LF, high HF, no liner | No |
| 2 | 12 | 17 | High LF, low HF, with liner | No |
| 2 | 13 | 18 | High LF, High HF, with liner | No |
| 3 | 6 | 11 | Low LF, Low HF, no liner | Yes |
| 3 | 7 | 12 | Low LF, high HF, no liner | Yes |
| 3 | 8 | 13 | Low LF, low HF, with liner | Yes |
| 3 | 9 | 14 | Low LF, High HF, with liner | Yes |
| 3 | 14 | 19 | High LF, Low HF, no liner | Yes |
| 3 | 15 | 20 | High LF, high HF, no liner | Yes |
| 3 | 16 | 21 | High LF, low HF, with liner | Yes |
| 3 | 17 | 22 | High LF, High HF, with liner | Yes |
| 4 | 18 | 23-24 | Vendor BKM | No |

Test 2: To determine if the reduction in antenna damage mentioned previously was due to clamping (which cools down the wafer to ˜300° C.), or simply due to the waiting that concurred during clamping, another test (test 2) was performed. Wafers were again split into four major groups. Group 1 consisted of a baseline PSG deposition using SACVD. Group 2 consisted of HDP-PSG processes in which wafers were clamped after deposition for different duration of time (10-40 second). Group 3 consisted of HDP-PSG processes in which wafers were left in the process chamber after deposition for different duration of time (30-90 second) without clamping. Group 4 used a vendor best known process in which the wafers were removed from the chamber immediately after deposition. See table II for split details.

TABLE II
Wafer split table in test 2.

| Group | Sub-Group | Wafer | Description | Clamp |
|---|---|---|---|---|
| 1 | 1 | 1-6 | SACVD PSG | N/A |
| 2 | 2 | 7-8 | 30s clamp | Yes |
| 2 | 3 | 9-10 | 40s clamp | Yes |
| 2 | 4 | 11-12 | 30s clamp | Yes |
| 2 | 5 | 13-14 | 20s clamp | Yes |
| 2 | 6 | 15-16 | 10s clamp | Yes |
| 3 | 7 | 17-18 | 30s wait | No |
| 3 | 8 | 19-20 | 60s wait | No |
| 3 | 9 | 21-22 | 90s wait | No |
| 4 | 10 | 23-24 | Vendor BKM | No |

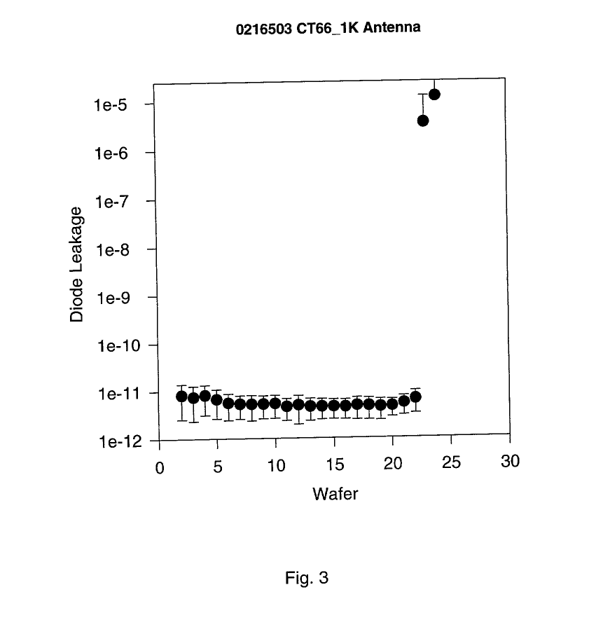

The results of test 2 are shown in FIG. 3. FIG. 3 shows that the antenna damage level in groups 3 (unclamped with 30-90 seconds waiting post process, wafers 17-22) is compatible to group 1 (SACVD, no plasma in deposition, wafers 1-6) and group 2 (clamp post process, wafer 7-16). Again, group 4 (vendor BKM, no clamp and no waiting, wafer 23-24) showed substantial diode leakage induced by antenna damage. This result demonstrated that a simple waiting period (without clamping) is also effective in reduce antenna damage.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

In the claims:

1. A method for fabricating an integrated circuit, comprising the steps of:
placing a semiconductor body in a process chamber;
exposing the semiconductor body to plasma excited gases;
allowing the plasma excited gases to discharge; and
then, removing the semiconductor body from the process chamber.

2. The method of claim 1, wherein the step of exposing the semiconductor body to plasma excited gases is part of a plasma deposition process.

3. The method of claim 1, wherein the step of exposing the semiconductor body to plasma excited gases is part of a plasma etch process.

4. The method of claim 1, wherein the semiconductor body is clamped during said allowing step.

5. The method of claim 4, wherein said allowing step continues until a temperature of the semiconductor body is around 300° C.

6. The method of claim 1, wherein the step of exposing the semiconductor body to plasma excited gases is part of a high density plasma process.

7. The method of claim 1, wherein a duration of said allowing step is in the range of 10-90 seconds.

8. A method of fabricating an integrated circuit comprising a plasma processing step, wherein said plasma processing step comprises the steps of:
placing a partially processed semiconductor wafer in a process chamber;
forming a plasma and exposing said semiconductor wafer to plasma excited gases;
performing a wait step to allow said plasma to be discharged; and
then, removing the semiconductor wafer from the process chamber.

9. The method of claim 8, wherein said plasma processing step is a plasma deposition process.

10. The method of claim 8, wherein said plasma processing step is a plasma etching process.

11. The method of claim 8, wherein said plasma processing step is a high density plasma process.

12. The method of claim 8, wherein said semiconductor wafer is clamped during said wait step.

13. The method of claim 12, wherein said semiconductor wafer is clamped until a temperature of the semiconductor wafer is around 300° C.

14. The method of claim 8, wherein said wait step has a duration in the range of 10-90 seconds.
